(19) United States
(12) Patent Application Publication
(10) Pub. No.: US 2006/0041818 A1
(43) Pub. Date: Feb. 23, 2006

(54) Method and apparatus for mitigating fading in a communication system

(75) Inventor: Shreharsha Rao, Dallas, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INC

(21) Appl. No.: 11/059,949

(22) Filed: Feb. 17, 2005

Related U.S. Application Data
(60) Provisional application No. 60/603,821, filed on Aug. 23, 2004.

(51) Int. Cl. H03M 13/00

(52) U.S. Cl. 714/755

(57) ABSTRACT

Systems and methods are provided for mitigating fading in a wireless communication system. A wireless communication, having an associated communication channel, includes a coder that provides coding to a digital input signal. A block interleaver has an associated interleaving depth and interleaving span. The associated interleaving span is selected as to achieve a target value for a normalized fading bandwidth associated with the channel. The block interleaver interleaves the coded input signal. A frequency hopping transmitter broadcasts the interleaved signal at a set of frequencies associated with the channel.

### RELATED APPLICATION

This application claims the benefit of provisional patent application No. 60/603,821, which was filed on Aug. 23, 2004 and entitled IMPROVING CODING GAIN, BIT ERROR RATE AND TRANSMISSION RANGE FOR A SLOWLY FADING INDOOR WIRELESS SYSTEM USING A COMBINATION OF CONVOLUTIONAL ENCODING, BLOCK INTERLEAVING AND SLOW FREQUENCY HOPPING, the entire disclosure of which is incorporated herein by reference.

### TECHNICAL FIELD

The present invention is directed generally to communication systems and is particularly directed to a method and apparatus for mitigating fading in a communication system.

### BACKGROUND

In the indoor propagation channel in the industrial, scientific, and medical (ISM) band, the transmit and receive antennas are generally either stationary or moving at very slow speeds. Accordingly, the degree of time variation within an indoor system is much less than that of an outdoor mobile system. One manifestation of time variation is spreading in the frequency domain, referred to as Doppler spreading. Given the typical indoor conditions, frequency spreading within the indoor propagation channel tends to be minimal. Empirical results bear this out, with typical Doppler spreads for this channel being measured in the range of 0.1-6.1 Hz (with RMS of about 0.3 Hz).

This low Doppler spread means that if the system is utilizing a frequency that is experiencing significant interference or is otherwise inhibited (e.g., the connection is in a fade), the connection recovers very slowly. If the transmitting and receiving antenna are stationary and there are no movements of any kind, the channel is essentially time invariant, with a Doppler spread near zero. The coherence time of the channel is inversely proportional to the Doppler spread and thus effectively approaches infinity. This implies that if the channel is in fade, it will remain so for the entire duration of a transmission. If the channel impulse response is characterized by a spectral null at a given transmission frequency, the entire message stream can be lost.

### SUMMARY

In accordance with one aspect of the present invention, a wireless communication system, having an associated communication channel, includes a coder that provides convolutional coding to a digital input signal. A block interleaver has an associated interleaving depth and interleaving span. The associated interleaving span is selected as a function of a target value for a normalized fading bandwidth associated with the channel. The block interleaver interleaves the coded input signal. A frequency hopping transmitter broadcasts the interleaved signal at a set of frequencies associated with the channel.

In accordance with another aspect of the present invention, a wireless communication system, having an associated communication channel, includes a frequency dehopper that recovers an interleaved signal from a frequency hopped signal broadcast on the communication channel. A deinterleaver reconstructs an error coded input signal from the recovered interleaved signal according to an interleaving depth and interleaving span associated with the interleaved signal. The associated interleaving span is selected to approximate a target value for a normalized fading bandwidth associated with the channel. A decoder retrieves a digital signal from the reconstructed error coded input signal. By of further example, a transceiver system can include both a transmitter system and a receiver system implemented according to an aspect of the present invention, in which the transmitter and receiver system may utilize the same or different communication channels.

In accordance with yet another aspect of the present invention, a method is provided for mitigating the effects of fading in a communication channel. A desired interleaving span is determined for a digital transmission according to a desired target value for the normalized fading bandwidth of the communication channel. A digital input signal is error coded via convolutional coding. The error coded signal is interleaved according to the determined interleaving span and a determined interleaving depth. The interleaved signal is transmitted as a frequency hopped signal across a plurality of frequencies associated with the channel from a first transceiver unit. The frequency hopped signal is dehopped at a second transceiver unit to recover the interleaved signal. The interleaved signal is deinterleaved to reconstruct the error coded signal. The error coded signal is decoded to retrieve the digital input signal.

### BRIEF DESCRIPTION OF THE DRAWINGS

The foregoing and other features and advantages of the present invention will become apparent to those skilled in the art to which the present invention relates upon reading the following description with reference to the accompanying drawings, in which:

FIG. 1 illustrates an indoor communications system in accordance with an aspect of the present invention.

FIG. 2 illustrates an exemplary implementation of a communication system in accordance with the present invention.

FIG. 3 illustrates a methodology for reducing fading in a transmission channel in accordance with an aspect of the present invention.

### DETAILED DESCRIPTION

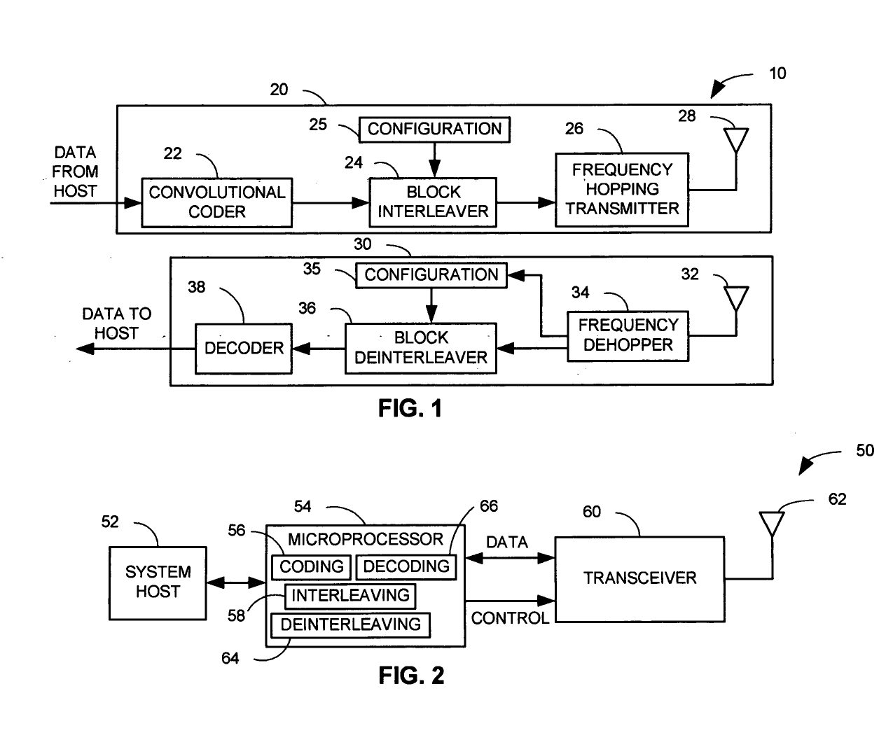

FIG. 1 illustrates an indoor communications system 10 in accordance with an aspect of the present invention. The illustrated system 10 utilizes a slow frequency hopping arrangement within an associated communication channel in combination with a reduced block interleaving matrix to simulate an infinitely interleaved data transmission channel. A slow frequency hopping arrangement generally can correspond to a system that provides more than one symbol per frequency. For example, the channel can comprise the indoor communications channel within the industrial, scientific, and medical (ISM) band designated by the United State or Europe. Other frequency bands can also be utilized by the system 10. A minimum interleaving depth and span of the block interleaving can be determined from the known Doppler spread and symbol duration of the channel, such that a normalized fading bandwidth of the channel can approximate (or exceed) a target value. The target value for the normalized fading bandwidth can be established as a threshold value that is sought to be achieved by the system 10. Accordingly, a channel behaving as an infinitely interleaved channel can be achieved with a minimal transmission delay.

The system 10 includes a transmitter system 20 that is operative to transmit data over a communications channel implemented as described herein. The transmitter system includes a coder that receives data from an associated host (not shown). For instance, the coder 22 can be a convolutional coder configured to code the data according to a desired convolutional coding scheme. In an exemplary embodiment, a rate of ½ coding can be utilized. Other types of coders and coding schemes can also be implemented by the transmitter system 20. The coded data is provided to a block interleaver 24.

The block interleaver 24 interleaves the data using an interleaving matrix having a desired interleaver depth and width (or span). An associated configuration component 25 can be employed to set an interleaving span. For instance, the configuration component 25 selects the interleaver span as a minimum span that is necessary to achieve the target value for the normalized fading bandwidth. The interleaving span can be set as a function of the interleaver depth given the data packet size, for example. The interleaver depth is typically equal to the number of frequencies in the hop-set for the communication channel. The configuration component 25 thus sets the depth and width of the interleaving matrix according to the data packet size and the number of frequencies. As an example, given an interleaver depth of 16 and a span of 128, the data packet size would equal 2048 symbols. The interleaver depth and span can be constant for a given channel, although it could be varied or modified according to changes in operating parameters. The block interleaver 24 provides the interleaved data to a frequency hopping transmitter 26.

The transmitter 26 transmits a frequency hopped signal via an antenna 28. The frequency hopped signal can have a plurality of associated frequencies based on the interleaved data. The transmitter 26 can utilize slow frequency hopping, such that a plurality of signals (e.g., more than one signal) are broadcast at a given frequency before the transmitter advances to a new frequency. The transmitter 26 can form part of an integrated transceiver, the receive portion for which is not shown in FIG. 1.

The transmitted signal can be received at a receiver system 30 at an associated antenna 32. The received signal is provided to a frequency dehopper 34 that recovers the transmitted signal from the frequency hopped transmission. The recovered signal can include configuration data, specifying a desired interleaving span and interleaving depth for the signal. The configuration data can be provided to a configuration component 35 associated with the receiver 30. The recovered signal is provided to a block deinterleaver 36 which reconstructs the signal according to an interleaving depth and interleaver width specified by the configuration component 35. The reconstructed signal is then provided to a decoder 38. For instance, the decoder 38 can be a Viterbi decoder that implements the Viterbi algorithm (e.g., a maximum likelihood decoder) to extract the original data from the convolutionally coded signal. The particular decoding will generally depend on the coding being implemented in the transmitter system 20. The data is then provided to an associated host (not shown) that is associated with the receiver 30.

It will be appreciated that the slow frequency hopping utilized by the communications system can result in burst errors due to fading at a frequency used to broadcast a set of contiguous symbols. The block interleaving used in the system divides these sets of contiguous symbols across a plurality of the hopping frequencies. Accordingly, the error caused by the fading of a given frequency is spread across a larger portion of the signal, reducing the correlation between faded symbols.

In accordance with an aspect of the present invention, the interleaving depth and interleaving span can be selected as to maintain the normalized fading bandwidth of the system at a desired level. The normalized fading bandwidth (NFB) of a given signal channel can be defined as the product of the Doppler spread, B_{D}, of the channel and the symbol duration, Tₛ, within the channel (e.g., NFB=B_{D}*Tₛ). The effective Doppler spread BD of the channel can be adjusted through the addition of interleaving, with the effective Doppler spread being expanded by a factor equal to the interleaving span (e.g., the effective B_{D}=B_{D} original*Interleaving span). Accordingly, by selecting a sufficiently large interleaving span, the normalized fading bandwidth of the channel can be increased to approximate a desired target value.

By way of further example, the error correction provided by Viterbi decoding becomes increasingly effective when the transmission channel is infinitely interleaved. Infinitely interleaving can be achieved as the normalized bandwidth of the channel approaches infinity. In accordance with an aspect of the present invention, performance comparable (e.g., within a few decibels) of an infinitely interleaved channel can be achieved by increasing the normalized fading bandwidth to a level that approximates or exceeds a given target value for the channel. For example, a normalized fading bandwidth in the vicinity of 0.1 has been found to be effective in one implementation of the communications system. By selecting a minimum interleaving span to approximate (e.g., 0.1) this target value, the required memory and processing delay necessary to implement the interleaving can also be reduced. An appropriate minimum interleaving depth can be selected according to the number of frequencies utilized by the frequency hopping transmitter 26 and the selected interleaving span. For example interleave depth can be set equal to number of frequency.

FIG. 2 illustrates an exemplary implementation of a communication system 50 in accordance with the present invention. On a transmit path of the system 50, a system host 52 provides a digital input to an associated microprocessor 54. For example, the microprocessor 54 can comprise a low power microprocessor, such as any microprocessor chip (e.g., model number MSP430) available from Texas Instruments, Inc. The microprocessor 54 can be programmed and/or configured as the baseband device of the communications system 50. For instance, the microprocessor 54 can include a coding algorithm 56 programmed to implement convolutional coding (or other coding schemes) on the digital input signal from the associated system host 52. For example, the error coding algorithm 56 can comprise a rate ½ convolutional coding algorithm that provides for encoding the digital data stream from the host 52 into blocks for transmission.

The microprocessor 54 can further include a block interleaving algorithm 58 that interleaves the error coded data according to an associated interleaving span and interleaving depth. The interleaving depth and interleaving span can be selected, for example, by a user or by an automated selection algorithm during the programming of the microprocessor 54. In accordance with an aspect of the present invention, the interleaving span can be selected to have a minimum value that provides a sufficiently large normalized fading bandwidth for the communication channel, according to known properties of the system (e.g., Doppler spread, symbol rate). The microprocessor 54 can also contain rules, such as part of the interleaving algorithm 58, for dynamically changing the interleaving depth and interleaving span according to changing characteristics of the signal and channel. For example, the interleaving span can be changed dynamically in response to changes in the signal rate. Similarly, the interleaving depth can be adjusted dynamically in response to changes in the frequency characteristics of the transmission channel.

The interleaved data is then provided to a transceiver 60 for transmission at an associated antenna 62. The transceiver 60 is operative to produce a frequency hopped signal that utilizes a plurality of frequencies across the communications channel. For example, the transceiver 60 can comprise a single chip radio frequency transceiver (e.g., the TRF6900A transceiver chip produced by Texas Instruments, Inc.). Those skilled in the art will understand and appreciated various other transceivers or separate transmitter and receiver portions that can be utilized in the system 50. The transceiver 60 can receive control instructions from the microprocessor 54 to control the frequency hopping of the transmission.

The communication system 50 also includes a receive path for providing data to the system host 52. A frequency hopped signal from another communication system (not shown) can be received at the antenna 62 and provided to the transceiver 60. The transceiver 60 is operative to dehop the frequency hopped signal to recover interleaved digital data from the received signal. This interleaved data is provided to the microprocessor 54. The microprocessor 54 includes a deinterleaving algorithm 64 that reconstructs an error coded digital signal from the interleaved data according to an associated interleaving depth and interleaving span. This interleaving depth and interleaving span can be provided as configuration data during the programming of the microprocessor. The configuration data can also be provided as control information from in the data received from the other communications system that provides the received signal. The interleaving depth and interleaving span can be altered dynamically for a given block of received data in response to a configuration signal provided with the data block. It will be appreciated, however, that the interleaving span can remain at or be adjusted to a value that maintains the normalized fading bandwidth that approximates a target level.

The microprocessor 54 can further comprise a decoding algorithm 66 that retrieves digital information from the error coded data. The decoding algorithm is programmed according to the type of coding scheme being implemented. For example, the decoding algorithm 66 can comprise a Viterbi decoder that decodes the convolutionally coded data to reconstruct a corresponding digital signal from the coded data in the received signal. The decoded data can then be provided to the system host 52.

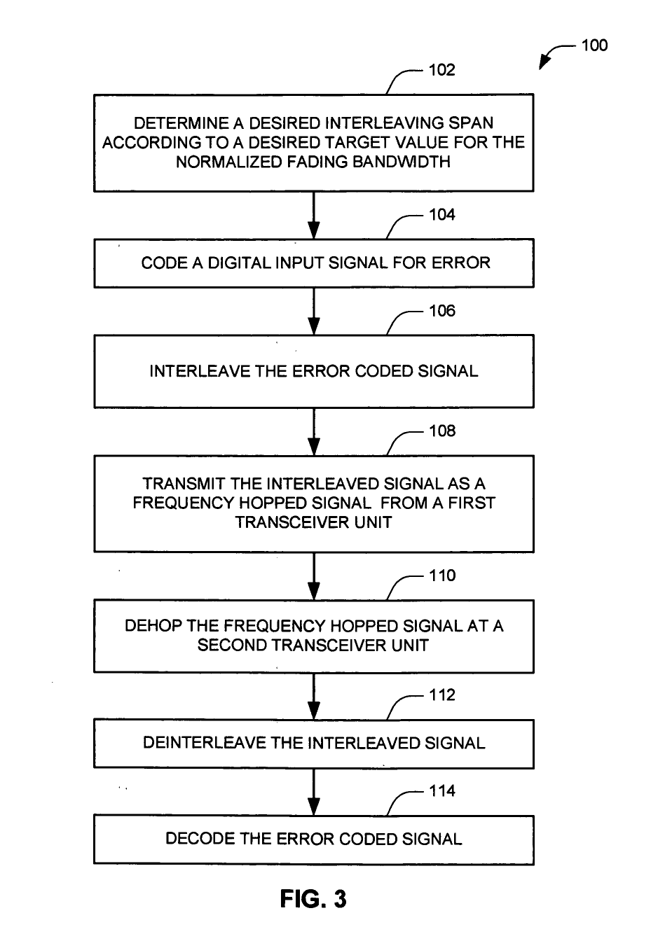

In view of the foregoing structural and functional features described above, a methodology in accordance with various aspects of the present invention will be better appreciated with reference to FIG. 3. While, for purposes of simplicity of explanation, the methodology of FIG. 3 is shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect the present invention.

FIG. 3 illustrates a methodology 100 for reducing fading in a transmission channel in accordance with an aspect of the present invention. At 102, a desired interleaving span is determined for a digital transmission according to a desired target value for the normalized fading bandwidth of the communication channel. For example, a minimum interleaving span can be calculated that is sufficient to approximate a target value for normalized fading bandwidth given known parameters of the channel, including symbol rate and Doppler spread of the channel. At 104, a digital input signal is error coded via convolutional coding.

At 106, the error coded signal is block interleaved according to the determined interleaving span and a determined interleaving depth. The interleaved signal is transmitted as a frequency hopped signal across a plurality of hopping frequencies associated with the channel from a first transceiver unit at 108. In an exemplary implementation, the interleaving depth is set equal to a number of hopping frequencies associated with the channel.

At 110, the frequency hopped signal is dehopped at a second transceiver unit to recover the interleaved signal. At 112, the interleaved signal is deinterleaved to reconstruct the error coded signal. The interleaving depth and interleaving span of the deinterleaving is configured to be equal to the interleaving span and interleaving depth used in the interleaving of the signal. This can be accomplished by configuring firmware in the first and second transceiver units to maintain static, equal values for the interleaving span and interleaving depth. Alternatively, the transmitted signal can include a configuration signal that provides the interleaving depth and interleaving span utilized by the first transceiver unit to the second transceiver unit. The methodology then proceeds to 114 where the error coded signal is decoded to retrieve the digital input signal. The methodology then terminates.

What has been described above includes exemplary implementations of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications, and variations that fall within the spirit and scope of the appended claims.

What is claimed is:

1. A wireless communication system, having an associated communication channel, comprising:
a coder that provides convolutional coding to a digital input signal;
a block interleaver, having an associated interleaving depth and interleaving span, that interleaves the coded input signal, the associated interleaving span being selected as a function of a target value for a normalized fading bandwidth associated with the channel; and
a frequency hopping transmitter that broadcasts the interleaved signal at a set of frequencies associated with the channel.

2. The system of claim 1, further comprising a configuration component that directs the block interleaver to utilize the selected interleaving span and provides a configuration message to the frequency hopping transmitter.

3. The system of claim 1, further comprising a configuration component that selects the interleaving span as a minimum interleaving span necessary to achieve the target value for the normalized fading bandwidth.

4. The system of claim 1, the interleaving depth associated with the block interleaver having a value equal to the number of frequencies in the set of frequencies associated with the channel.

5. The system of claim 1, the coder and the block interleaver being implemented computer executable instructions by microprocessor.

6. The system of claim 1, wherein the coder, block interleaver and the frequency hopping transmitter form at least a portion of a transmitter system, the system further comprising at least one receiver system, the at least one receiver system comprising:
a frequency dehopper that recovers an interleaved signal from a frequency hopped broadcast signal;
a deinterleaver that reconstructs a coded signal from the recovered interleaved signal according to an interleaving depth and interleaving span associated with the interleaved signal; and
a decoder that decodes the reconstructed coded signal to provide a digital output signal.

7. The system of claim 6, the receiver further comprising a configuration component that is operative to receive configuration data from the frequency dehopper, determine an appropriate interleaving depth and interleaving span for the deinterleaver from the configuration data, the deinterleaver employing the appropriate interleaving depth and interleaving span to provide the reconstructed coded signal.

8. The system of claim 6, the frequency hopped transmitter and the frequency dehopper implemented as a single chip radio frequency (RF) transceiver.

9. The system of claim 6, wherein the coder comprises a convolutional encoder and the decoder comprises a Viterbi decoder.

10. The system of claim 1, the wireless communication system being an indoor wireless communication system, and the communication channel being located within one of the United States industrial, scientific, and medical (ISM) band and the European ISM band.

11. A wireless communication system, having an associated communication channel, comprising:
a frequency dehopper that recovers an interleaved signal from a frequency hopped signal broadcast on the communication channel;
a deinterleaver that reconstructs an error coded input signal from the recovered interleaved signal according to an interleaving depth and interleaving span associated with the interleaved signal, the associated interleaving span being selected as to approximate a target value for a normalized fading bandwidth associated with the channel; and
a decoder that retrieves a digital signal from the reconstructed error coded input signal.

12. The system of claim 11, the interleaving span being selected as a minimum interleaving span to approximate the target value for the normalized fading bandwidth.

13. The system of claim 11, the decoder and the deinterleaver being implemented as respective software algorithms within a microprocessor.

14. The system of claim 11, wherein the decoder and the deinterleaver form part of a receive path implemented as respective software algorithms within a microprocessor of the system, the frequency dehopper being implemented as part of a radio frequency (RF) transceiver, the system further comprising a transmit path that comprises:
a coder that performs coding on a digital input signal to provide a coded input signal;
a block interleaver, having an associated interleaving depth and interleaving span, that interleaves the coded input signal to provide an interleaved signal, the associated interleaving span being selected as to approximate a target value for an normalized fading bandwidth associated with a second channel, the coder and block interleaver being implemented as respective software algorithms within the microprocessor of the system; and
a frequency hopping transmitter, which is part of the RF transceiver, that broadcasts the interleaved signal at a set of frequencies associated with the second channel.

15. The system of claim 11, further comprising a configuration component that is operative to receive a configuration message from the frequency dehopper and provide a desired interleaving depth and interleaving span to the deinterleaver in response to the configuration message.

16. The system of claim 11, wherein the decoder, the deinterleaver and the dehopper form part of a receiver system, the system of claim 11 further comprising at least one transmitter system, which is separate from the receiver system, the at least one transmitter system comprising:
a coder that provides a coded signal by performing convolutional coding on a digital input signal;
a block interleaver, having an associated interleaving depth and interleaving span, that interleaves the coded input signal, the associated interleaving span being selected as to approximate a target value for an normalized fading bandwidth associated with the channel; and
a frequency hopping transmitter that broadcasts the interleaved signal at a set of frequencies associated with the channel.

17. A method for mitigating fading in a communication channel comprising:
determining an interleaving span for a digital transmission according to a desired target value for a normalized fading bandwidth of the communication channel;
error coding a digital input signal;
interleaving the error coded signal according to the determined interleaving span and;
transmitting the interleaved signal as a frequency hopped signal across a plurality of hopping frequencies associated with the channel from a first transceiver unit;
dehopping the frequency hopped signal at a second transceiver unit to recover the interleaved signal;
deinterleaving the interleaved signal to reconstruct the error coded signal; and
decoding the error coded signal to retrieve the digital input signal.

18. The method of claim 17, wherein decoding the error coded signal comprises performing Viterbi decoding on the error coded signal.

19. The method of claim 17, determining a desired interleaving span includes calculating a minimum interleaving span that will approximate a target normalized fading bandwidth given a known symbol rate and Doppler spread of the channel.

20. The method of claim 17, further comprising determining a desired interleaving depth according to the number of hopping frequencies associated with the channel.
